(19) United States
(12) Patent Application Publication
(10) Pub. No.: US 2022/0334221 A1
(43) Pub. Date: Oct. 20, 2022

(54) LIDAR

(71) Applicant: SUTENG INNOVATION TECHNOLOGY CO., LTD., Shenzhen (CN)

(72) Inventor: Shen JIANG, Shenzhen (CN)

(73) Assignee: SUTENG INNOVATION TECHNOLOGY CO., LTD., Shenzhen (CN)

(21) Appl. No.: 17/852,481

(22) Filed: Jun. 29, 2022

Related U.S. Application Data
(63) Continuation-in-part of application No. PCT/CN2020/070252, filed on Jan. 3, 2020.

(30) Foreign Application Priority Data
Dec. 31, 2021 (CN) 202123445766.5

(51) Int. Cl. G01S 7/48; G01S 17/10; G01S 17/89; H05K 7/20

(52) U.S. Cl. CPC G01S 7/4802; G01S 17/10; G01S 17/89; H05K 7/20409

(57) ABSTRACT

The present disclosure relates to a LiDAR. An embodiment of the present invention realizes a control function, a processing function, an emitting function, a receiving function, and an interface function of the LiDAR via each independent board to prevent components from causing a heat accumulation effect. In addition, according to the embodiments of the present disclosure, the digital plate for digital signal processing and the analog plate for analog signal processing are separately arranged to reduce electromagnetic interference between analog signals and digital signals, thereby further reducing the internal interference of the LiDAR.

### CROSS-REFERENCE TO RELATED APPLICATION

The present application is a continuation-in-part of International Application No. PCT/CN2020/070252, filed on Jan. 3, 2020, and claims the benefit of priority to China Patent Application No. CN202123445766.5, filed Dec. 31, 2021, the contents of which are both incorporated herein by reference in their entireties.

### TECHNICAL FIELD

The present invention relates to the field of measurement, and in particular, to LiDAR.

### BACKGROUND

LiDAR is a radar system that emits a laser beam to detect the position and speed of an object. The working principle of the LiDAR is to first emit a detection laser beam to the object, then compare signals reflected from the object with emitting signals, and properly process the signals to obtain relevant information of the object, such as an object distance, an azimuth, a height, a speed, an attitude, a shape and other parameters. In the field of autonomous driving, a vehicle LiDAR is configured to detect a pedestrian, a vehicle, other obstacles, etc. The volume of the vehicle LiDAR is becoming smaller and smaller. The problem of heat dissipation and electromagnetic interference of the vehicle LiDAR is increasingly prominent. When heat generated by a component in the LiDAR is accumulated, the temperature of a local component increases, which affects the measurement performance of the LiDAR. Similarly, the increasingly serious electromagnetic interference among various components of the LiDAR causes waveform distortion on the components, which also affects the measurement performance of the LiDAR. How to improve the heat dissipation performance and anti-interference ability of the LiDAR is a problem that needs to be solved urgently.

### SUMMARY

An embodiment of the present invention provides a LiDAR, which solves the problems of poor heat dissipation performance and large internal interference of the LiDAR in the related art.

In order to solve the above technical problems, the embodiments of the present invention disclose the following technical solutions.

According to a first aspect, the present invention provides a LiDAR, including:

a housing, an analog plate, a digital plate, an emitting plate, a receiving plate, a galvanometer, and an interface plate, wherein the analog plate, the digital plate, the emitting plate, and the receiving plate are arranged inside the housing, and

wherein the emitting plate is configured to emit an emergent laser;

wherein the receiving plate is configured to receive a reflected laser formed by the emergent laser passing through a target object, and to convert the reflected laser into first electrical signals;

wherein the galvanometer is configured to directionally deflect the emergent laser and the reflected laser;

wherein the analog plate is configured to control the deflection angle of the galvanometer, and to condition the first electrical signals to obtain second electrical signals;

wherein the digital plate is configured to sample the second electrical signals to obtain sampled signals, and to generate a scanned image according to the sampled signals; and

wherein the receiving plate includes a communication interface and a power interface, and wherein the communication interface is configured to communicate with an external apparatus and the power interface is configured to input an external voltage signal.

In a possible design, the LiDAR also includes:

a window heating sheet connected to the interface plate and configured to convert electrical energy from the interface plate into thermal energy.

In a possible design, the interface plate further includes:

a heating circuit, a bus voltage-stabilizing circuit, a power protection circuit, and an interface protection circuit,

wherein the power protection circuit is configured to perform overvoltage protection and overcurrent protection on the interface plate;

wherein the bus voltage-stabilizing circuit is configured to perform voltage stabilization processing on external voltage signals to obtain bus voltage signals;

wherein the heating circuit is configured to use the bus voltage signals to transmit electrical energy to the window heating sheet; and

wherein the interface protection circuit is configured to suppress interference of the communication interface.

In a possible design, the interface plate further includes a first heat dissipation component, and wherein the bus voltage-stabilizing circuit is attached to an inner wall of the housing via the first heat dissipation component.

In a possible design, the window heating sheet is connected to the interface plate via a socket.

In a possible design, the digital plate includes:

a main controller, a storage device, a watchdog circuit, a clock circuit, a sampling circuit, and a first power supply circuit,

wherein the storage device is configured to store a computer program;

wherein the watchdog circuit is configured to reset the main controller when the main controller fails;

wherein the clock circuit is configured to generate clock signals;

wherein the sampling circuit is configured to take sample of the second electrical signals according to the clock signals to obtain sampled signals;

wherein the main controller is configured to call the computer program to process the sampled signals to obtain a scanned image; and

wherein the first power supply circuit is configured to convert the bus voltage signals into a plurality of working voltage signals with different voltage values, and provides the plurality of working voltage signals for each circuit in the digital plate.

In a possible design, the digital plate is divided into an analog signal region and a digital signal region, wherein

the clock circuit, the sampling circuit, and the first power supply circuit are positioned in the analog signal region, and the main controller, the memory, and the watchdog circuit are positioned in the digital signal region.

In a possible design, the digital plate further includes a second heat dissipation component, wherein

the main controller, the sampling circuit and the first power supply circuit are attached to an inner wall of the housing via the second heat dissipation component.

In a possible design, the analog plate includes an emitting power supply circuit, an echo conditioning circuit, a receiving power supply circuit, a galvanometer drive circuit, a second power supply circuit, and a control unit,

wherein the second power supply circuit is configured to convert the bus voltage signals into first voltage signals and second voltage signals;

wherein the emitting power supply circuit is configured to use the first voltage signals to supply power to the emitting plate;

wherein the receiving power supply circuit is configured to use the second voltage signals to supply power to the receiving plate;

wherein the echo conditioning circuit is configured to receive the first electrical signals from the receiving plate, and condition the first electrical signals to obtain the second electrical signals;

wherein the control unit is configured to generate galvanometer drive signals, and send the galvanometer drive signals to the galvanometer drive circuit; and

wherein the galvanometer drive circuit is configured to adjust a deflection angle of the galvanometer according to the galvanometer drive signals.

In a possible design, the analog plate is divided into a digital signal region and an analog signal region, wherein

the control unit is positioned in the digital signal region, and the emitting power supply circuit, the echo conditioning circuit, the receiving power supply circuit, the galvanometer drive circuit, and the second power supply circuit are positioned in the analog signal region.

In a possible design, the digital plate further includes a third heat dissipation component,

wherein a printed circuit plate of the emitting plate is attached to the inner wall of the housing via the third heat dissipation component;

wherein the emitting plate is connected to the analog plate via a flexible flat cable; and

wherein the material of the printed circuit plate in the emitting plate is ceramics.

In a possible design, a first shielding cover is provided on the emitting plate to electromagnetically shield the emitting plate.

In a possible design, a second shielding cover is provided on the receiving plate to electromagnetically shield the receiving plate. The receiving plate further includes a signal amplifier. The signal amplifier is configured to amplify the first electrical signals.

In a possible design, the analog plate and the digital plate are stacked.

In this embodiment, the LiDAR includes the housing, the analog plate, the digital plate, the emitting plate, the receiving plate, the interface plate, and the galvanometer. The analog plate, the digital plate, the emitting plate, and the receiving plate are arranged inside the housing. The various functions of the LiDAR are realized via a plurality of boards, so as to avoid the problems of poor heat dissipation and damage to components caused by implementing all functions of LiDAR in the related art by one board. An embodiment of the present invention implements a control function, a processing function, an emitting function, a receiving function, and an interface function of the LiDAR via each independent board, to prevent components from generating a heat accumulation effect. In addition, according to the present invention, the digital plate for digital signal processing and the analog plate for analog signal processing are separately arranged to reduce electromagnetic interference between analog signals and digital signals, thereby further reducing the internal interference of the LiDAR.

### BRIEF DESCRIPTION OF DRAWINGS

In order to explain embodiments of the present invention or the technical solutions in the related art more clearly, the following briefly introduces the drawings that need to be used in the embodiments. Obviously, the drawings in the following description are only some embodiments of the present invention. The person skilled in the art may obtain other drawings based on these drawings without creative work.

FIG. 1A shows a framework schematic diagram of a LiDAR according to an embodiment of the present invention;

FIG. 1B shows a schematic structural diagram of a LiDAR according to an embodiment of the present invention;

FIG. 1C shows a schematic diagram of the positions of various boards according to an embodiment of the present invention;

FIG. 1D shows an assembly schematic diagram according to an embodiment of the present invention;

FIG. 2 shows a schematic structural diagram of an interface plate in a LiDAR according to an embodiment of the present invention;

FIG. 3 shows a schematic structural diagram of a digital plate in a LiDAR according to an embodiment of the present invention;

FIG. 4 shows a schematic structural diagram of an analog plate in a LiDAR according to an embodiment of the invention;

FIG. 5 shows another schematic structural diagram of a LiDAR according to an embodiment of the present invention;

FIG. 6A is a schematic structural diagram of a LiDAR according to an embodiment of this application;

FIG. 6B is a schematic structural diagram of a LiDAR according to an embodiment of this application;

FIG. 7A is a schematic structural diagram of a transceiver module according to an embodiment of this application;

FIG. 7B is a schematic diagram of a connection of an emitting plate according to an embodiment of this application;

FIG. 7C is a schematic structural diagram of an emitting plate and a receiving plate according to an embodiment of this application;

FIG. 8A is a schematic structural diagram of a processing plate according to an embodiment of this application;

FIG. 8B is a schematic structural diagram of another processing plate according to an embodiment of this application;

FIG. 8C is a schematic structural diagram of a processing plate according to an embodiment of this application;

FIG. 9 is a schematic structural diagram of an interface plate according to an embodiment of this application;

FIG. 10A is a schematic structural diagram of another interface plate according to an embodiment of this application;

FIG. 10B is a schematic structural diagram of a housing of a LiDAR according to an embodiment of this application; and

FIG. 11 is a schematic structural diagram of an electronic device according to an embodiment of this application.

### DETAILED DESCRIPTION

The following embodiments of the present invention provide a LiDAR. Functions of the LiDAR are realized by a plurality of independent boards to reduce accumulation of heat generated by components in the LiDAR, which causes the failure of the components. In addition, digital signals and analog signals are processed via different boards, thereby reducing the internal interference of the LiDAR. Therefore, an embodiment of the present invention may improve heat dissipation performance and anti-interference ability of the LiDAR, and increase the reliability of the LiDAR.

The following clearly and completely describes the technical solutions in the embodiments of the present invention in conjunction with the drawings in the embodiments of the present invention. Obviously, the described embodiments are only a part of the embodiments of the present invention, rather than all embodiments. Based on the embodiments of the present invention, all other embodiments obtained by the person skilled in the art without creative work shall fall within the protection scope of the present invention.

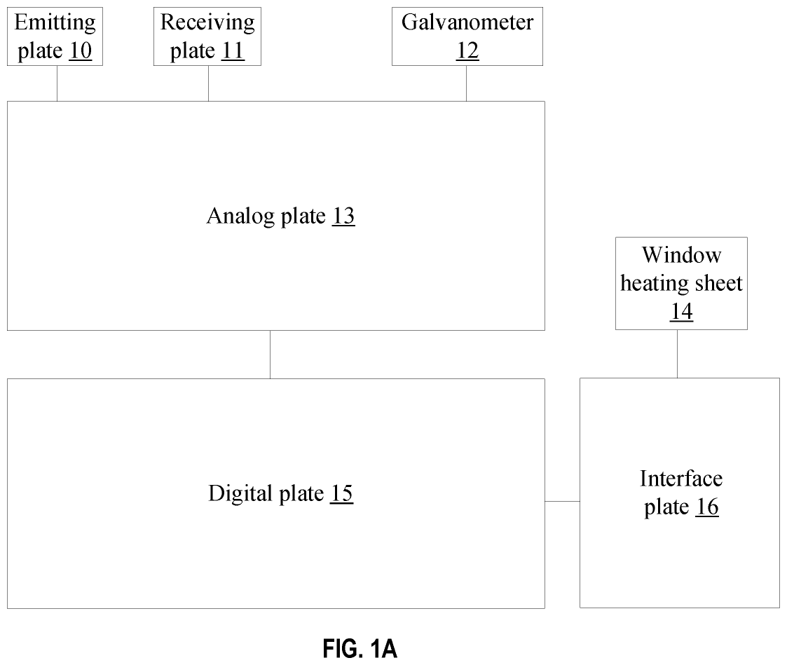

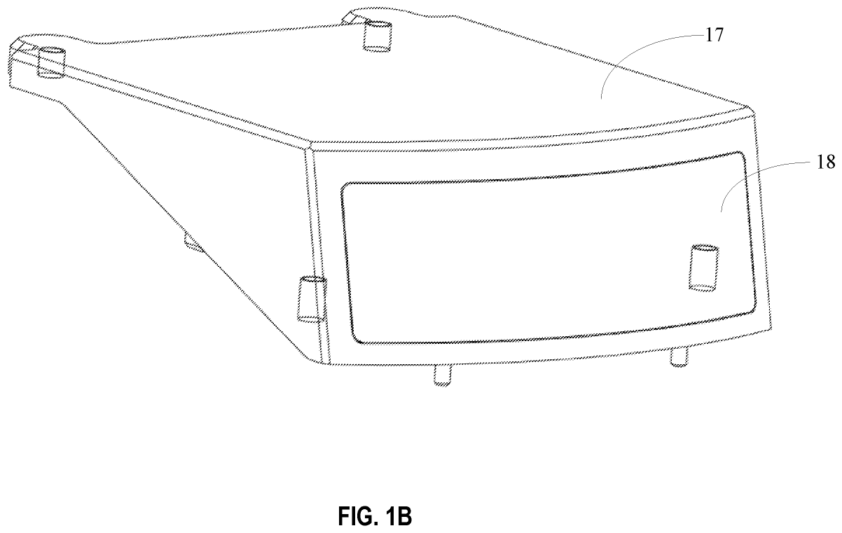

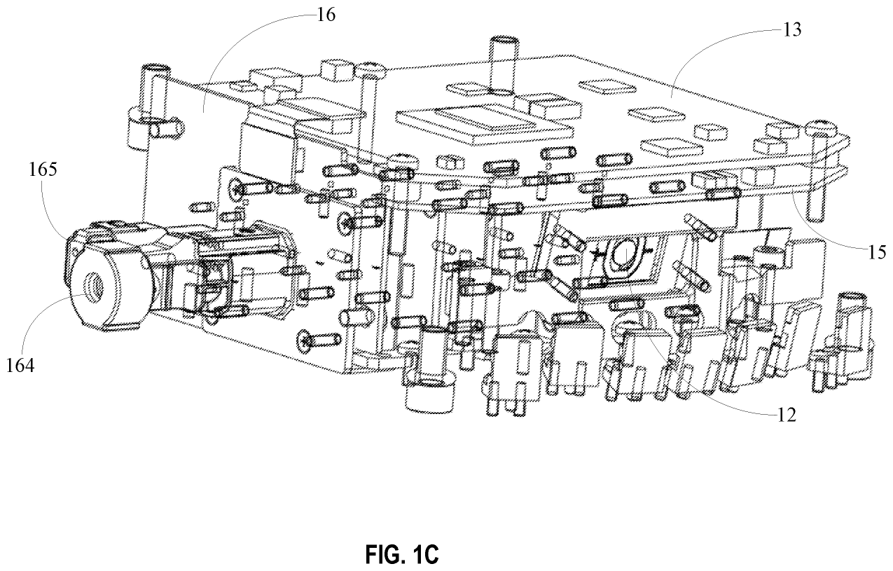

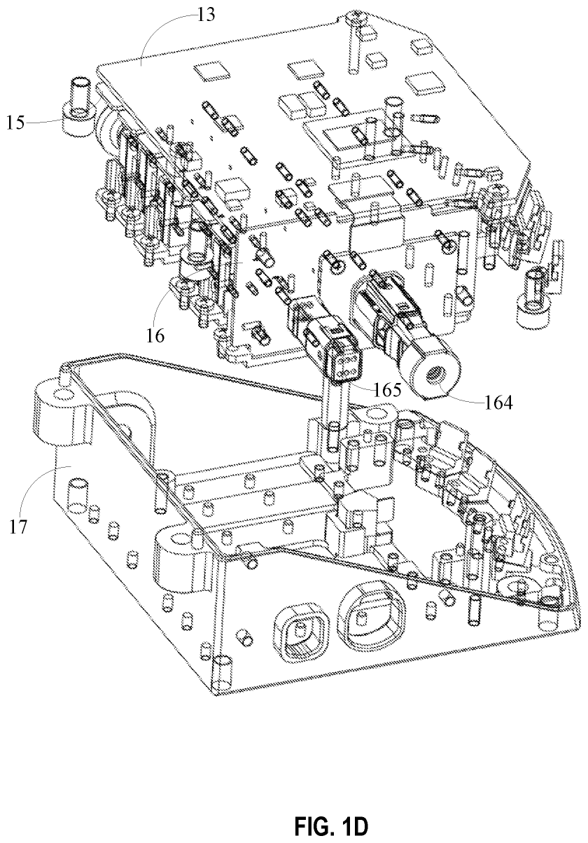

FIG. 1A-FIG. 1D show schematic diagrams of the LiDAR according to an embodiment of the present invention. The LiDAR includes a housing 17, an emitting plate 10, a receiving plate 11, a galvanometer 12, an analog plate 13, a window heating sheet 14, a digital plate 15 and an interface plate 16. The interface plate 16 is provided with a power interface 164 and a communication interface 165.

The emitting plate 10, the galvanometer 12, the receiving plate 11, the analog plate 13, the digital plate 15, and the interface plate 16 are arranged in the housing 17. The emitting plate 10, the receiving plate 11, the analog plate 13, and the digital plate 15 are boards. A board consists of a printed circuit plate and a plurality of components arranged on the printed circuit plate. The connection between the emitting plate 10 and the analog plate 13 is an electrical connection. For example, the emitting plate 10 and the analog plate 13 are electrically connected via a flexible flat cable or a socket. The connection between the receiving plate 11 and the analog plate 13 is an electrical connection. For example, the receiving plate 11 and the analog plate 13 are connected via a flexible flat cable. The connection between the galvanometer 12 and the analog plate 13 is an electrical connection. For example, the galvanometer 12 and the analog plate 13 are electrically connected via a flexible flat cable or a socket. The connection between the analog plate 13 and the digital plate 15 is an electrical connection. For example, the analog plate 13 and the digital plate 15 are electrically connected via a socket. The connection between the digital plate 15 and the interface plate 16 is an electrical connection. For example, the digital plate 15 and the interface plate 16 are electrically connected via a socket. The connection between the interface plate 16 and the window heating sheet 14 is an electrical connection. For example, the interface plate 16 and the window heating sheet 14 are electrically connected via a socket. As shown in FIG. 1B, a window sheet 18 is arranged on the housing 17 of the LiDAR. The emergent laser generated by the LiDAR and the reflected laser received by the LiDAR pass through the window sheet 18. The window sheet 18 is made of a material with high light transmittance. Optionally, the analog plate 13 and the digital plate 15 are stacked to reduce the volume of the LiDAR. For example, as shown in FIG. 1C and FIG. 1D, the analog plate 13 is positioned under the digital plate 15. The digital plate is a core digital part that realizes the LiDAR functions. Compared with the analog plate, components on the digital plate have higher power consumption and require higher heat dissipation. The digital plate is arranged above the analog plate so that the digital plate is closer to the housing 17, which may better conduct heat on the digital plate to the outside via the housing 17, thereby improving overall heat dissipation efficiency.

The working principle of the LiDAR in the embodiments of the present invention is described in detail below.

The emitting plate 10 is configured to emit the emergent laser. The number of the emitting plate 10 may be one or more. The emitting plate 10 may emit the emergent laser according to a preset laser frequency and a preset emitting period. The frequency and the period of the emergent laser may be determined according to actual needs, which is not limited to the embodiments of the present invention. The emergent laser is deflected by the galvanometer 12 and irradiates a target object. For example, the emitting plate 10 is provided with a laser device, an emitting terminal collimating unit, a central circular hole emitting lens, and a receiver. The laser device is configured to generate the emergent laser. The emitting terminal collimating unit is configured to collimate the emergent laser emitted by the laser device. The central circular hole reflecting mirror includes a central circular hole and an edge mirror and is configured to allow the collimated emergent laser to penetrate out of the central circular hole and irradiate the galvanometer 12.

The receiving plate 11 is configured to receive the reflected laser formed by the emergent laser passing through the target object, and to convert the reflected laser into first electrical signals. The emergent laser irradiates the target object to form the reflected laser. The receiving plate 11 receives the reflected laser via a receiving mirror. The receiving mirror focuses the reflected laser and transmits the emergent laser to a photoelectric converter. The photoelectric converter converts the reflected laser into the first electrical signals. For example, the photoelectric converter on the receiving plate 11 may include any one of APD (Avalanche Photodiode), PIN (Positive Intrinsic-Negative), APD in Geiger mode, and a single photon receiver, as well as silicon photomultiplier such as avalanche photodiode APD, MPPC (Multi Pixel Photon Counters), and SiPM, or may consist of a single array or a plurality of arrays of the forgoing functional devices.

The galvanometer 12 is configured to directionally deflect the emergent laser emitted by the emitting plate 10. The analog plate 13 sends out galvanometer drive signals to the galvanometer 12 to control the deflection angle of the galvanometer 12, thereby directionally deflecting the emergent laser. For example, the analog plate 13 controls the galvanometer 12 to scan in horizontal and vertical directions in a sinusoidal manner. The galvanometer 12 may be a one-dimensional galvanometer or a two-dimensional galvanometer. For example, the galvanometer 12 may be a MEMS (Micro-Electro-Mechanical System) galvanometer, or other mechanical or electronic galvanometer.

The analog plate 13 is configured to control the deflection angle of the galvanometer 12. The deflection angle of the galvanometer 12 is configured to control the deflection direction of the emergent laser. The analog plate 13 sends the galvanometer drive signals to the galvanometer 12. The galvanometer drive signals may be a sine wave signal. The frequency and amplitude of the sine wave may be determined according to actual needs. In addition, the analog plate 13 also collects the feedback signals of the galvanometer 12 (for example: a horizontal deflection angle and a vertical deflection angle, etc.), and realizes a closed-loop control of the galvanometer 12 according to the feedback signals. For example, the frequency of the sine wave signals is equal to or approximately equal to the resonance frequency of the galvanometer 12. The galvanometer drive signals control the galvanometer 12 to scan, using a corresponding scanning mode. The scanning mode may be any one of a sine wave mode, a cosine wave mode, or a triangle wave mode. The analog plate 13 is also configured to condition the first electrical signals generated by the receiving plate 11 to obtain the second electrical signals. The conditioning process includes, but is not limited to, one or more of debouncing, filtering, protection, level conversion, and isolation.

The digital plate 15 is configured to sample the second electrical signals to obtain the sampled signals, and to generate a scanned image according to the sampled signals. The scanned image includes a plurality of point clouds. The positions of the point clouds are related to the deflection angle of the galvanometer 12 in horizontal and vertical directions. The detection distance is related to the intensity of the reflected laser.

The interface plate 16 includes a communication interface and a power interface. The communication interface is configured to communicate with an external apparatus. The communication interface includes, but is not limited to, a RS232 interface, a USB interface, or a CAN interface. The power interface is configured to input external voltage signals. The LiDAR uses the external voltage signals to supply power to each board.

The window heating sheet 14 is connected to the interface plate 16. The window heating sheet is configured to convert electrical energy from the interface plate 16 into thermal energy. The window heating sheet 14 consists of a high-resistance material to improve the efficiency of converting electrical energy into thermal energy. The window heating sheet 14 is tightly attached to the window sheet 18 in FIG. 1B to defrost the window sheet 18 in FIG. 1B, thereby preventing the water vapor of the window sheet 18 from affecting the intensity and direction of the emergent laser and the reflected laser. The connection between the window heating sheet 14 and the interface plate 16 is an electrical connection. For example, the window heating sheet 14 and the interface plate 16 are electrically connected via the socket.

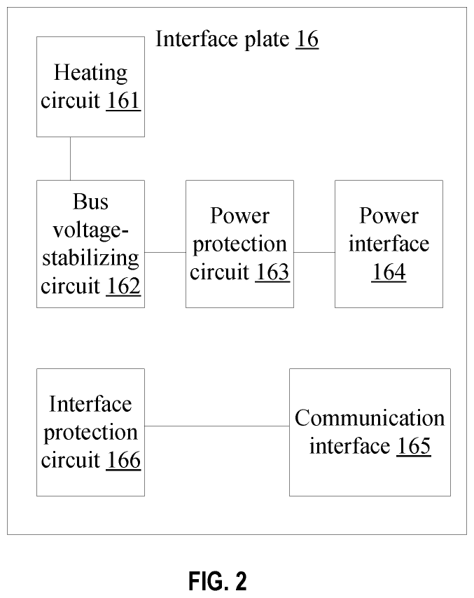

In a possible implementation, as shown in FIG. 1C, FIG. 1D and FIG. 2, the interface plate 16 includes a heating circuit 161, a bus voltage-stabilizing circuit 162, a power protection circuit 163, a power interface 164, a communication interface 165, and an interface protection circuit 166. The power interface 164 is configured to input external voltage signals. For example, the external voltage signals are 5V DC voltage signals. The power protection circuit 163 is configured to perform overvoltage protection and overcurrent protection for the interface plate, thereby preventing excessive transient voltage or current from causing damage to the components of the LiDAR. In addition, the power protection circuit 163 is also configured to filter out interference of an external power supply to the LiDAR, and the interference of the LiDAR to the external power supply. The bus voltage-stabilizing circuit 162 is configured to stabilize the external voltage signals to obtain the bus voltage signals, and to stabilize those external voltage signals with voltage fluctuations to obtain target voltage signals with a constant voltage value, thereby ensuring the stability of a post-stage power supply. The heating circuit 161 is electrically connected to the window heating sheet 14. The heating circuit 161 uses the bus voltage signals to transmit electrical energy to the window heating sheet 14. The bus voltage signals are loaded on the window heating sheet 14. The window heating sheet 14 converts electrical energy into thermal energy and transfers the thermal energy to a lens of the galvanometer 12 and a receiving lens of the receiving plate 11 to defrost the lens. The communication interface 165 is configured to communicate with the external apparatus. The LiDAR receives instructions or data sent by the external apparatus via the communication interface 165. Alternatively, the LiDAR sends instructions or data to the external apparatus via the communication interface 165. The interface protection circuit 166 is configured to protect the communication interface 165, such as overvoltage protection, overcurrent protection, interference suppression, etc., to improve the reliability of communication. It may be understood that the bus voltage-stabilizing circuit 163 in the interface plate 16 is a main heat source.

Further, the interface plate 16 further includes a first heat dissipation component. The first heat dissipation component may be made of a material with high thermal conductivity. For example, the material of the first heat dissipation component is aluminum, ceramics, or the like. Since the bus voltage-stabilizing circuit 163 in the interface plate is the main heat source, the bus voltage-stabilizing circuit 163 is attached to an inner wall of the housing via the first heat dissipation component. Heat generated by the bus voltage-stabilizing circuit 163 is quickly transferred to the housing, thereby improving the heat dissipation efficiency of the voltage-stabilizing circuit 163.

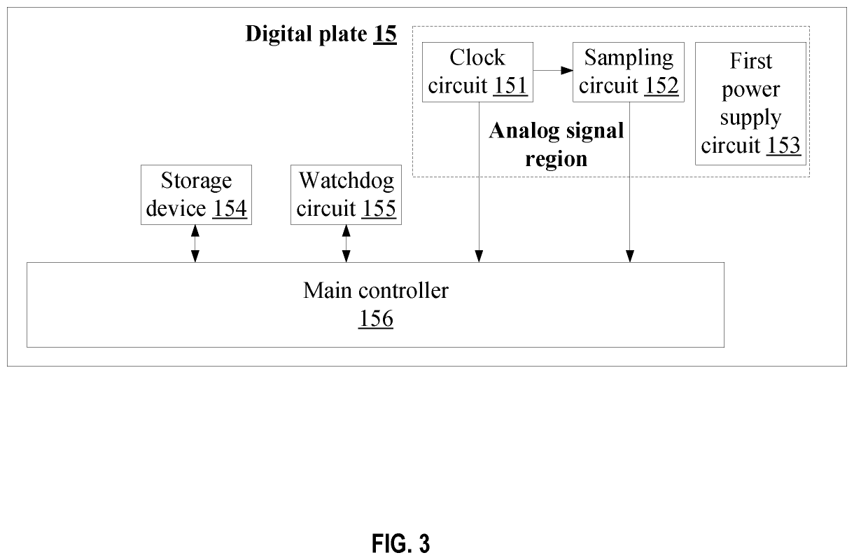

In a possible implementation, as shown in FIG. 3, the digital plate 15 includes a clock circuit 151, a sampling unit 152, a first power supply circuit 153, a storage device 154, a watchdog circuit 155 and a main controller 156. The storage device is configured to store a computer program. The watchdog circuit 155 is also referred to as a watchdog timer and is a timer circuit. The watchdog circuit 155 is configured to reset the main controller 156 when the main controller 156 fails. The main controller periodically sends pulse signals to the watchdog circuit 155, namely, kicking the dog (kicking the dog/service the dog). When the main controller 156 fails (for example, executes an infinite loop), the main controller 156 cannot send pulse signals to the watchdog circuit 155. When the watchdog circuit 155 does not receive the pulse signals within a preset time period, the watchdog circuit 155 sends reset signals to the main controller 156 to instruct the main controller 156 to perform a reset operation. The clock circuit 151 is configured to: generate clock signals, provide a working clock for the main controller 156, and provide a sampling clock for the sampling circuit 152. The sampling circuit 152 samples the first electrical signals from the analog plate 13 according to a preset sampling frequency to obtain the sampled signals. The main controller 156 calls the computer program stored in the storage device 154 to process the sampled signals to obtain the scanned image. The main controller 156 may be a central processing unit (CPU), a network processor (NP) or a combination of a CPU and NP. The processor may further include a hardware chip. The forgoing hardware chip may be an application-specific integrated circuit (ASIC), a programmable logic device (PLD), or a combination thereof. The forgoing PLD may be a complex programmable logic device (CPLD), a field-programmable gate array (FPGA), a generic array logic (GAL) or any combination thereof. The main controller 156 is also connected to the communication interface 165 in the interface plate 16 and the main controller 156 communicates with the external apparatus via the communication interface 165. The main controller 156 is also configured to send control signals to the control unit in the analog plate 13 to control the emitting plate 10 to emit the emergent laser, and to control the receiving plate 11 to receive the reflected laser. The first power supply circuit 153 is configured to convert the bus voltage signals into a plurality of working voltage signals of different voltage values, and to supply power to each circuit in the digital plate 15. It may be understood that the heat source of the digital plate 15 is mainly concentrated on the main controller 156, the sampling circuit 152, and the first power supply circuit 153.

Further, the digital plate 15 is divided into an analog signal region and a digital signal region. The clock circuit 151, the sampling circuit 152, and the first power supply circuit 153 are positioned in the analog signal region. The storage device 154, the watchdog circuit 155 and the main controller 156 are positioned in the digital signal region. The embodiment of the present invention isolates the digital signals from the analog signals on the digital plate 15 to reduce interference between the digital signals and the analog signals.

Further, the digital plate 15 further includes a second heat dissipation component. The second heat dissipation component is made of high thermal conductivity material. For example, the second heat dissipation component is a compressible soft gasket. The second heat dissipation component is filled between the main heat sources in the housing and the digital plate 15. The main controller 156, the sampling circuit 152, and the first power supply circuit 153 are tightly attached to an inner wall of the housing via the second heat dissipation component. As the main controller 156, the sampling circuit 152, and the first power supply circuit 153 are the main heat sources of the digital plate 15. The foregoing three components transfer heat generated to the housing via the second heat dissipation component, thereby improving the heat dissipation efficiency of the digital plate 15.

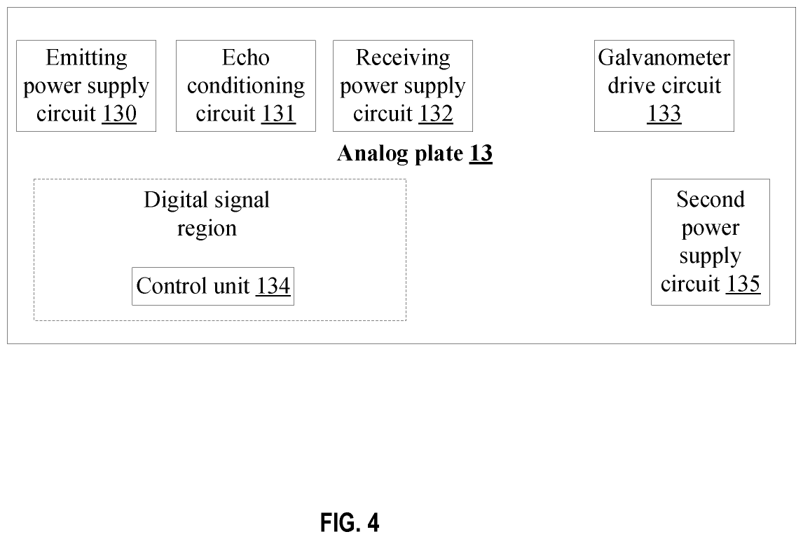

In a possible implementation, as shown in FIG. 4, the analog plate 13 includes an emitting power supply circuit 130, an echo conditioning circuit 131, a receiving power supply circuit 132, a galvanometer drive circuit 133, a control unit 134, and a second power supply circuit 135. The second power supply circuit 135 is configured to convert the bus voltage signals into a plurality of voltage signals of different voltage values. The plurality of voltage signals include first voltage signals and second voltage signals. The first voltage signals and the second voltage signals have different voltage values. The emitting power supply circuit 130 is configured to use the first voltage signals to supply power to the emitting plate 10. The receiving power supply circuit 132 is configured to use the second voltage signals to supply power to the receiving plate 11. The echo conditioning circuit 131 is configured to condition the first electrical signals from the receiving plate 11 to obtain the second electrical signals, and the conditioning process includes one or more of debouncing, filtering, protection, level conversion, and isolation. The control unit 134 is configured to generate the galvanometer drive signals and send the galvanometer drive signals to the galvanometer drive circuit, thereby controlling the galvanometer 12 to scan, using the corresponding scanning mode. The control unit 134 may control the emitting plate 10 to emit the emergent laser and control the receiving plate 11 to receive the reflected laser according to the instructions of the main controller. The galvanometer drive circuit 133 is configured to adjust the deflection angle of the galvanometer according to the galvanometer drive signals. The galvanometer drive signals may be the superposition of a triangle wave signal and a sine wave signal to control the galvanometer to scan in the horizontal and vertical directions.

Further, the analog plate 13 is divided into a digital signal region and an analog signal region. The control unit 134 is positioned in the digital signal region. The emitting power supply circuit 130, the echo conditioning circuit 131, the receiving power supply circuit 132, the galvanometer drive circuit 133, and the second power supply circuit are located in the analog signal region. By isolating the digital signals from the analog signals on the analog plate 13, the interference between the digital signals and the analog signals is reduced.

In a possible implementation, the LiDAR further includes a third heat dissipation component. The third heat dissipation component is made of a high thermal conductivity material. The printed circuit plate of the emitting plate 10 is attached to an inner wall of the housing via the third heat dissipation component to transfer the heat generated by the emitting plate 10 to the housing, thereby improving the heat dissipation efficiency of the emitting plate 10. The emitting plate 10 may be connected to the analog plate 13 via a flexible flat cable, and the material of the printed circuit plate in the emitting plate 10 is ceramics.

In a possible implementation, a first shielding cover is provided on the emitting plate 10. The material of the first shielding cover is metal. The first shielding cover covers the components of the emitting plate 10 and is configured to shield electromagnetic signals of the emitting plate 10, thereby preventing the electromagnetic signals generated by the emitting plate 10 from causing interference to other components.

In a possible implementation, a second shielding cover is provided on the receiving plate 11. The material of the second shielding cover is metal. The second shielding cover covers the components of the receiving plate 11 and is configured to shield electromagnetic signals of the receiving plate 11, thereby preventing the electromagnetic signals generated by the receiving plate 11 from causing interference to other components. In addition, the receiving plate 11 also includes a signal amplifier for amplifying first signals, so as to further improve the anti-interference ability of the receiving plate 11.

In this embodiment, the LiDAR includes the housing, the analog plate, the digital plate, the emitting plate, the receiving plate, the interface plate, and the galvanometer. The analog plate, the digital plate, the emitting plate, and the receiving plate are arranged inside the housing. The various functions of the LiDAR are realized via a plurality of boards, so as to avoid the problems of poor heat dissipation and damage to components caused by implementing all functions of the LiDAR in the related art by one board. An embodiment of the present invention realizes a control function, a processing function, an emitting function, a receiving function, and an interface function of the LiDAR by each independent board, to prevent the components from generating a heat accumulation effect. In addition, according to the present invention, the digital plate for digital signal processing and the analog plate for analog signal processing are separately arranged to reduce electromagnetic interference between analog signals and digital signals, thereby further reducing the internal interference of the LiDAR.

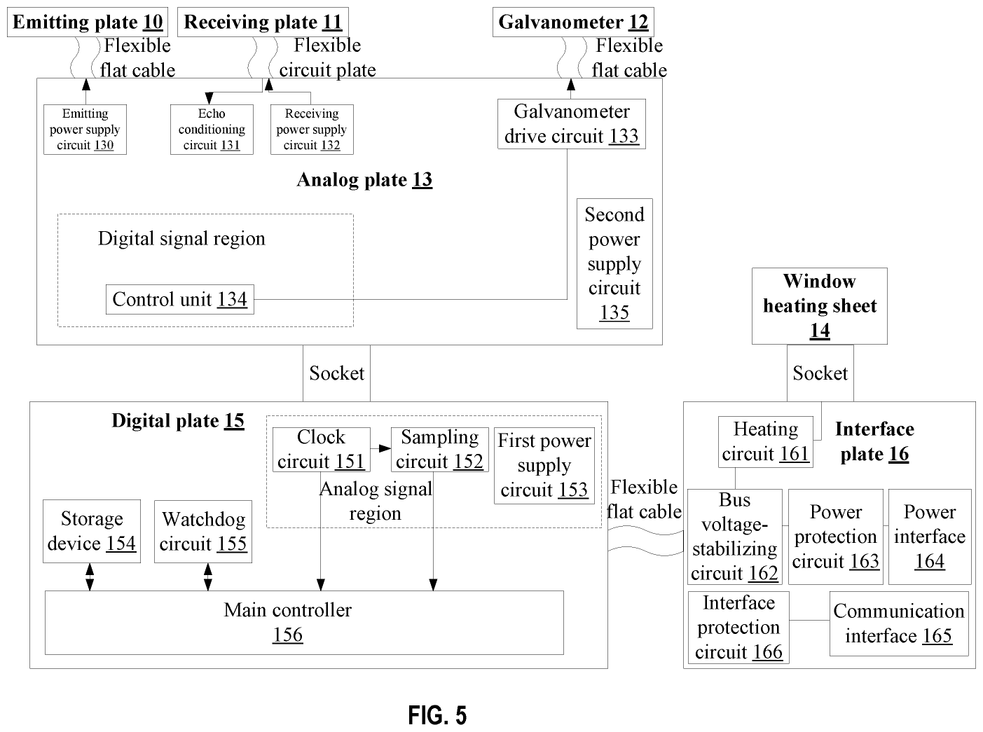

FIG. 5 is another schematic structural diagram of a LiDAR provided by an embodiment of the present invention. In this embodiment of the application, the LiDAR includes a housing (not shown in FIG. 5), an emitting plate 10, a receiving plate 11, a galvanometer 12, an analog plate 13, a window heating plate 14, a digital plate 15, and an interface plate 16. The analog plate 13 includes an emitting power supply circuit 130, an echo conditioning circuit 131, a receiving power supply circuit 132, a galvanometer drive circuit 133, a control unit 134, and a second power supply circuit 135. The digital plate 15 includes a clock circuit 151, a sampling unit 152, a first power supply circuit 153, a storage device 154, a watchdog circuit 155, and a main controller 156. The interface plate 16 includes a heating circuit 161, a bus voltage-stabilizing circuit 162, a power protection circuit 163, a power interface 164, a communication interface 165, and an interface protection circuit 166. The analog plate 13 is divided into two independent signal regions, a digital signal region and an analog signal region (not shown in FIG. 5). The control unit 134 is positioned in the digital signal region. The emitting power supply circuit 130, the echo conditioning circuit 131, the receiving power supply circuit 132, the galvanometer drive circuit 133, and the second power supply circuit 135 are positioned in the analog signal region. The digital plate 15 is also divided into two independent signal regions, a digital signal region and an analog signal region (not shown in FIG. 5). The clock circuit 151, the sampling circuit 152, and the first power supply circuit 153 are positioned in the analog signal region. The storage device 154, the watchdog circuit 155, and the main controller 156 are positioned in the digital signal region. The interface plate 16 also includes a first heat dissipation component (not shown in FIG. 5). The first heat dissipation component may be made of a material with high thermal conductivity. Since the bus voltage-stabilizing circuit 163 in the interface plate is the main heat source, the bus voltage-stabilizing circuit 163 is attached to an inner wall of the housing via the first heat dissipation component. Heat generated by the bus voltage-stabilizing circuit 163 is quickly transferred to the housing, thereby improving the heat dissipation efficiency of the voltage-stabilizing circuit 163. The digital plate 15 further includes a second heat dissipation component (not shown in FIG. 5). The second heat dissipation component may be made of high thermal conductivity material. For example, the second heat dissipation component is made of aluminum or ceramics. The main controller 156, the sampling circuit 152, and the first power supply circuit 153 are tightly attached to the inner wall of the housing via the second heat dissipation component. As the main controller 156, the sampling circuit 152, and the first power supply circuit 153 are the main heat sources of the digital plate 15, the foregoing three components transfer heat generated to the housing via the second heat dissipation component, thereby improving the heat dissipation efficiency of the digital plate 15. The printed circuit plate of the emitting plate 10 is attached to the inner wall of the housing via a third heat dissipation component to transfer the heat generated by the emitting plate 10 to the housing, thereby improving the heat dissipation efficiency of the emitting plate 10. The emitting plate 10 may be connected to the analog plate 13 via a flexible flat cable, and the material of the printed circuit plate in the emitting plate 10 is ceramics. A first shielding cover is provided on the emitting plate 10. The material of the first shielding cover is metal. The first shielding cover covers the components of the emitting plate 10 and is configured to shield the electromagnetic signals of the emitting plate 10, thereby preventing the electromagnetic signals generated by the emitting plate 10 from causing interference to other components. A second shielding cover is provided on the receiving plate 11. The material of the second shielding cover is metal. The second shielding cover covers the components of the receiving plate 11 and is configured to shield the electromagnetic signals of the receiving plate 11, thereby preventing the electromagnetic signals generated by the receiving plate 11 from causing interference to other components. In addition, the receiving plate 11 also includes a signal amplifier for amplifying first signals, so as to further improve the anti-interference ability of the receiving plate 11.

The connection relationship of the various components in FIG. 5 is as follows: the emitting plate 10 is connected to the emitting power supply circuit 130 in the analog plate 13 via a flexible flat cable. The receiving plate 11 is connected to the echo conditioning circuit 131 and the receiving power supply circuit 132 in the analog plate 13 via a flexible circuit plate. The galvanometer 12 is connected to the galvanometer drive circuit 133 in the analog plate 13 via the flexible flat cable. The control unit 134 is connected to the galvanometer drive circuit 133. The second power supply circuit 135 is connected to the emitting power supply circuit 130, the echo conditioning circuit 131, the receiving power supply circuit 132, the galvanometer drive circuit 133, and the control unit 134 in the analog plate 13 (not shown in FIG. 5). The analog plate 13 and the digital plate 15 are electrically connected via a socket. The main controller 156 is connected to the control unit 134 in the analog plate 13 (not shown in FIG. 5) via a socket. The storage device 154 is connected to the main controller 156. The watchdog circuit 155 is connected to the main controller 156. The clock circuit 151 is connected to the main controller 156 and the sampling circuit 152. The first power supply circuit 153 is connected to the clock circuit 151, the sampling circuit 152, the storage device 154, the watchdog circuit 155, and the main controller 156 (not shown in FIG. 5). The digital plate 15 is connected to the interface plate 16 via a flexible flat cable. The window heating sheet 14 is connected to the heating circuit 161 of the interface plate 16 via a socket. The heating circuit 161 is connected to the bus voltage-stabilizing circuit 162. The bus voltage-stabilizing circuit 162 is connected to the power protection circuit 163. The power protection circuit 163 is connected to the power interface 164. The receiving protection circuit 166 is connected to the communication interface 165.

The workflow of each component in FIG. 5 includes:

The power interface 164 is configured to input external voltage signals. The power protection circuit 163 is configured to perform overvoltage protection and overcurrent protection for the interface plate 16. The bus voltage-stabilizing circuit 162 is configured to stabilize the external voltage signals to obtain bus voltage signals. The heating circuit 161 is configured to heat the window heating sheet 14 using the bus voltage signals. The communication interface 165 is an interface for data transmission between the main controller 156 and an external apparatus. The interface protection circuit 166 is configured to suppress interference of the communication interface 165.

The emitting plate 10 is configured to emit the emergent laser. The receiving plate 11 is configured to receive the reflected laser formed by the emergent laser passing through a target object, and to convert the reflected laser into first electrical signals. The galvanometer 12 is configured to deflect the emergent laser directionally. The second power supply circuit 135 is configured to convert the bus voltage signals into first voltage signals and second voltage signals. The emitting power supply circuit 130 is configured to use the first voltage signals to supply power to the emitting plate 10. The receiving power supply circuit 132 is configured to use the second voltage signals to supply power to the receiving plate 11. The echo conditioning circuit 131 is configured to receive the first electrical signals from the receiving plate 11, and to condition the first electrical signals to obtain the second electrical signals. The control unit 134 is configured to generate galvanometer drive signals, and to send the galvanometer drive signals to the galvanometer drive circuit 133. The galvanometer drive circuit 133 is configured to adjust the deflection angle of the galvanometer 12 according to the galvanometer drive signals.

The storage device 154 is configured to store a computer program. The watchdog circuit 155 is configured to reset the main controller when the main controller fails. The clock circuit 151 is configured to generate clock signals. The sampling circuit 152 is configured to sample the second electrical signals to obtain sampled signals. The main controller 156 is configured to call the computer program to process the sampled signals to obtain a scanned image. The first power supply circuit 153 is configured to convert the bus voltage signals into a plurality of working voltage signals of different voltage values. The plurality of working voltage signals are provided to each circuit in the digital plate.

For the specific implementation process of each circuit in FIG. 5, please refer to the description in FIG. 2 to FIG. 4, which will not be repeated here.

The embodiment of the present invention may optimize heat dissipation, that is, improve the heat dissipation efficiency of the LiDAR, and achieve electromagnetic interference optimization, that is, improve the anti-interference ability of the LiDAR.

Regarding heat dissipation optimization, the main heat sources of the LiDAR are distributed on the interface plate, the digital plate, and the emitting plate. The bus voltage-stabilizing circuit of the interface plate is tightly attached to a side of a housing of the LiDAR. Heat of the bus voltage-stabilizing circuit is conducted to the housing via the heat dissipation component, thereby improving heat dissipation efficiency. The main controller, a collecting circuit, and a power supply circuit on the digital plate are tightly attached to the top surface of the housing of the LiDAR. The heat of the circuits is conducted to the housing via a heat dissipation gasket, thereby improving the heat dissipation efficiency. The material of the emitting plate is a ceramic plate with high thermal conductivity. The heat dissipation component is attached to the bottom of the LiDAR to conduct heat to the housing, thereby improving the heat dissipation efficiency. On the whole, the main heat source on each plate in the entire LiDAR is close to the housing to facilitate heat dissipation, thereby reducing the internal temperature rise of the whole machine.

Regarding the optimization of electromagnetic interference, on an external interface, only the interface plate of the entire LiDAR is connected to the outside. Interference isolation is achieved on the interface. On the one hand, the interference isolation resists the interference of external interference signals on the inner part of the LiDAR, and on the other hand, the interference isolation suppresses interference of internal interference signals of the LiDAR on the external interface, thereby achieving a good electromagnetic compatibility design. In the internal circuit design of the LiDAR, the analog plate and the digital plate are strictly divided into the analog signal region and the digital signal region. The digital signal region and the analog signal region are spatially isolated, thereby reducing the interference between the analog signals and the digital signals, ensuring the reliability of analog signal quality and the digital signal quality, and guaranteeing the overall anti-interference ability of the LiDAR.

In addition, in the embodiment of the present invention, the emitting plate and the receiving plate are designed as independent boards. There is very strong electromagnetic radiation interference inside the emitting plate. After being designed as the independent boards, a shielding cover is added to shield the electromagnetic radiation interference. On the one hand, the shielding cover reduces the interference of the emitting plate to other internal circuit parts of the LiDAR, and on the other hand, the shielding cover reduces the overall external radiation interference of the whole machine. A receiving sensor on the receiving plate outputs weak signals, which is very susceptible to external interference. After being designed as the independent boards, the shielding cover is added to shield the board, thereby reducing electromagnetic radiation interference of other circuits inside the LiDAR or outside the LiDAR. In addition, the signal amplification circuit is provided inside the receiving plate. Amplified signals have stronger anti-interference ability, thereby ensuring the quality of echo signals and the performance of the LiDAR in various electromagnetic interference environments.

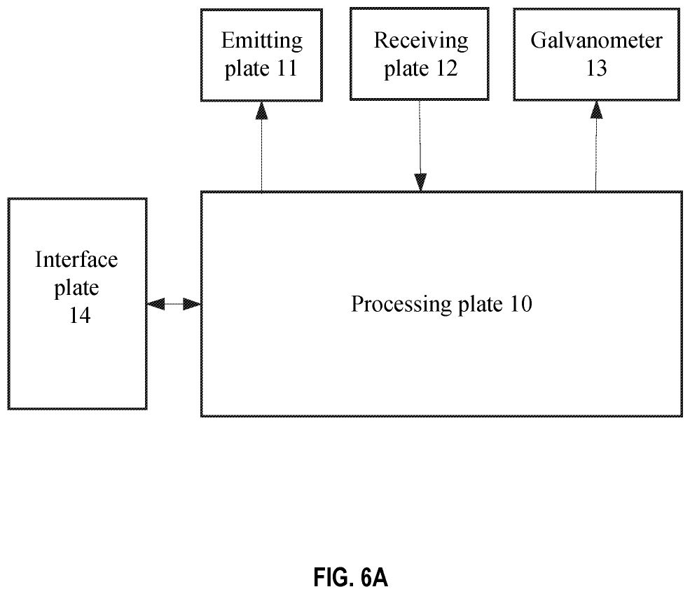

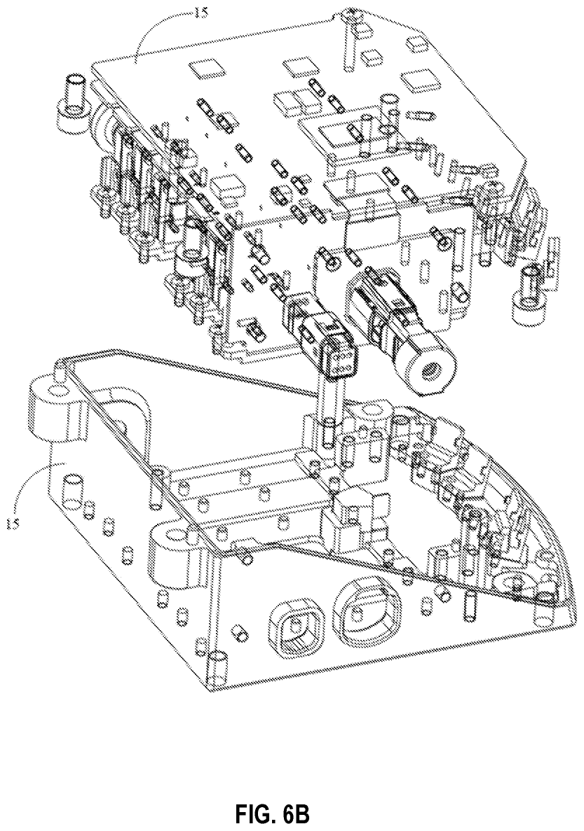

Referring to FIG. 6A, FIG. 6A is another schematic structural diagram of a LiDAR according to an embodiment of this application. An analog plate and a digital plate may be combined into one board. As shown in FIG. 6A, the LiDAR includes a housing (not shown in FIG. 6A), a processing plate 10, a transceiver module (including an emitting plate 11 and a receiving plate 12), a galvanometer 13, and an interface plate 14. Referring to FIG. 6B, FIG. 6B is a schematic structural diagram of a housing of a LiDAR according to an embodiment of this application. The LiDAR includes a housing 15.

The processing plate 10, the emitting plate 11, the receiving plate 12, the galvanometer 13, and the interface plate 14 are arranged inside the housing 15. The first end of the interface plate 14 is connected to the first end of the processing plate 10. The second end, the third end, and the fourth end of the processing plate 10 are respectively connected to the emitting plate 11, the receiving plate 12, and the galvanometer 13. The foregoing connection method is an electrical connection. For example, the emitting plate 11 and the processing plate 10 are electrically connected through a flexible flat cable or a socket, and the galvanometer 13 and the processing plate 10 are electrically connected through the flexible flat cable or the socket. This application includes any electrical connection method.

The processing plate 10, the emitting plate 11, the receiving plate 12, and the interface plate 14 are a type of board, and the board is composed of a printed circuit plate and a plurality of components arranged on the printed circuit plate.

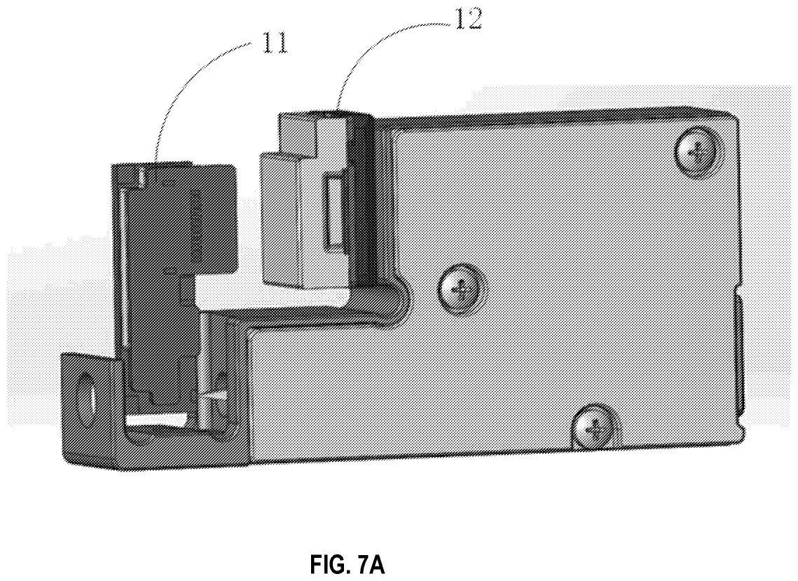

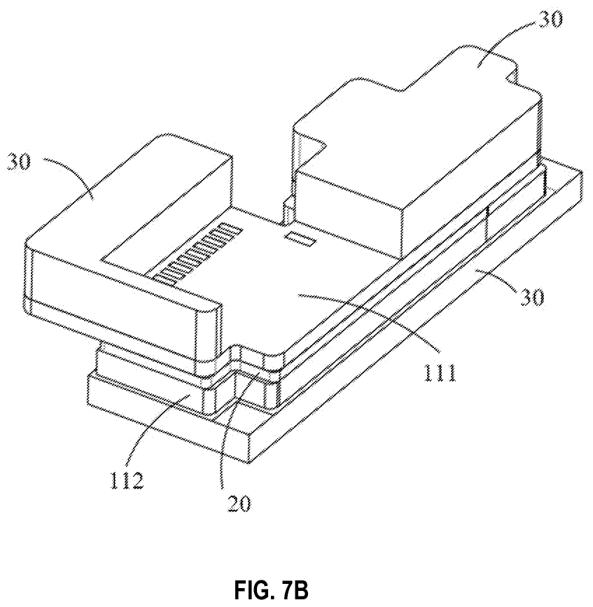

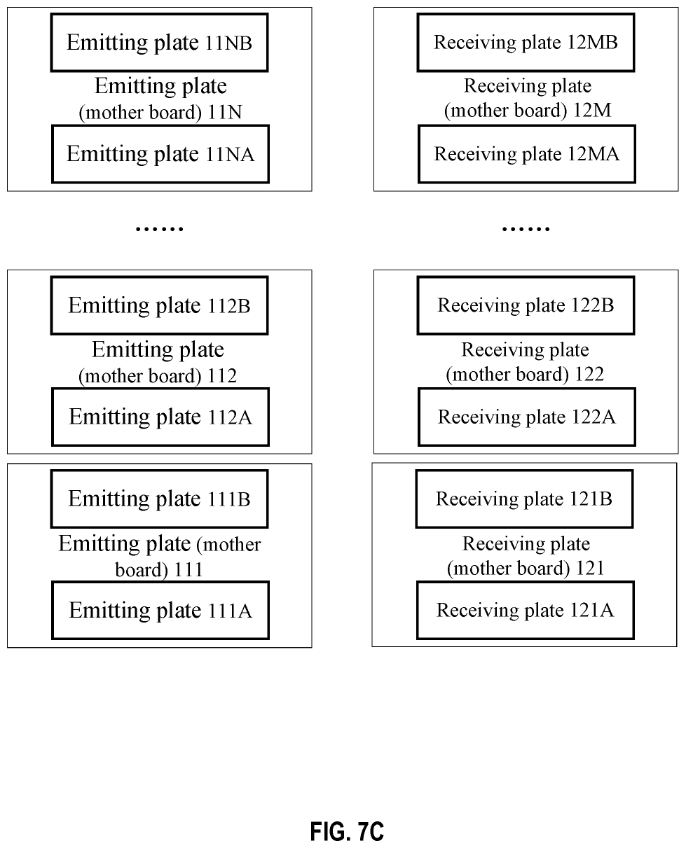

A transceiver module includes an emitting plate 11, an emitting terminal collimating unit, a beam splitter, a receiving terminal focusing unit and a receiving plate 12. Referring to FIG. 7A, FIG. 7A is a schematic structural diagram of a transceiver module according to an embodiment of this application. The transceiver module includes an emitting plate 11, a receiving plate 12, and an accommodating cavity. The accommodating cavity is configured to accommodate the emitting terminal collimating unit, the beam splitter, and the receiving terminal focusing unit (not shown in the figure).

The emitting plate 11 is configured to transmit a laser signal. Specifically, the emitting plate 10 can transmit an emergent laser according to preset laser power and a preset transmission period, and then the emergent laser passes through the emitting terminal collimating unit and the beam splitter in the accommodating cavity before being transmitted out. The laser signal transmitted is deflected by the galvanometer 13 and then directed to a target object to scan a field of view. The receiving plate 12 is configured to collect an echo signal returned after the laser signal is reflected by the target object. The receiving plate 12 is configured to receive the echo signal after the laser signal is reflected by the target object, and to convert the echo signal into an electrical signal. After the laser signal is directed to the target object and reflected by the target object, the echo signal is returned, and the galvanometer 13 receives the echo signal and reflects the echo signal back to the transceiver module in the original path. The echo signal is directed to a photoelectric converter after passing through the beam splitter and the receiving terminal focusing unit in the transceiver module, and the photoelectric converter converts the echo signal into the electrical signal. For example, the photoelectric converter on the receiving plate 12 can include any one or more of APD, PIN, APD in a Geiger mode, and a single-photon receiver, as well as silicon photomultiplier such as avalanche photodiode APD, MPPC (Multi Pixel Photon Counters,), and SiPM (silicon photomultiplier), or can be composed of one or more arrays of the foregoing functional devices. It can be understood that frequency and a period of the emergent laser signal can be determined according to actual needs. This is not limited in the embodiments of this application.

In an embodiment, as shown in FIG. 7B, FIG. 7B is a schematic diagram of a connection of multiple emitting plates according to an embodiment of this application. A first emitting plate 111, a second emitting plate 112, a heat dissipation component 30, and a support element 20 are included. Each emitting plate at least includes one transmitting sub-board, and the first emitting plate 111 and the second emitting plate 112 are arranged on the housing 15 by using the heat dissipation component 30, to use the heat dissipation component 30 to conduct heat generated during operation to the housing 15. The first emitting plate 111 and the second emitting plate 112 are connected and fixed via the support element 20. It can be understood that two emitting plates are connected in this application, and this application can also include a connection method of another number of emitting plates.

Each emitting plate is in a form of two layered boards of a mother board and a sub-board, and at least one sub-board of the emitting plate is arranged on each mother board of the emitting plate. Referring to FIG. 7C, FIG. 7C is a schematic structural diagram of an emitting plate and a receiving plate according to an embodiment of this application. Each transceiver module includes N emitting plates and M receiving plates, where N and M are positive integers greater than or equal to 1, and N may or may not be equal to M.

In this embodiment, each receiving plate and each emitting plate are in the form of two layered boards of a mother board and a sub-board. FIG. 7C shows an emitting plate (mother board) 111, an emitting plate (mother board) 112, . . . , an emitting plate (mother board) 11N, and a receiving plate (mother board) 121, a receiving plate (mother board) 122, . . . , a receiving plate (mother board) 12M. Each mother board of the receiving plate is provided with at least one sub-board of the receiving plate, and each mother board of the emitting plate is provided with at least one sub-board of the emitting plate. For example, the emitting plate (mother board) 111 is provided with two sub-boards of the emitting plate, namely, an emitting plate 111A and an emitting plate 111B; and the receiving plate (mother board) 121 is provided with two sub-boards of the receiving plate, namely, a receiving plate 111A and a receiving plate 111B. It can be understood that description that each mother board corresponds to two sub-boards in this application is only used as an example, and this application also includes a case that one mother board corresponds to any number of sub-boards.

In this embodiment, the mother board of the emitting plate 11 is a rigid-flex board, and the sub-board is a ceramic board with heat dissipation coefficient exceeding a threshold. As the ceramic board, the sub-board can evenly distribute heat of the emitting plate 11 to reduce temperature rise, and a combination of the rigid-flex board and the ceramic board can save space and enhance heat dissipation to the greatest extent.

In another embodiment, a structure of the receiving plate is similar to that shown in FIG. 7B. Details are not described herein again.

In an embodiment, shielding covers are respectively provided on the emitting plate 11 and/or the receiving plate 12 to provide electromagnetic shielding for the emitting plate or the receiving plate. For example, the emitting plate 11 is provided with a first shielding cover, and the receiving plate 12 is provided with a second shielding cover. A material of the shielding cover is metal, and the shielding cover covers a component of the emitting plate 11 and/or the receiving plate 12, and is configured to shield an electromagnetic signal of the emitting plate 11 and/or the receiving plate 12, thereby preventing the electromagnetic signals generated by the emitting plate 11 and/or the receiving plate 12 from causing interference to another component.

The LiDAR includes multiple transceiver modules arranged abreast, and a structure of each transceiver module is shown in FIG. 7A. For example, the transceiver module includes N emitting plates 11 and M receiving plates 12. A connection method of the N emitting plates 11 is shown in FIG. 7B, and a structure of each emitting plate 11 is shown in FIG. 7C.

A processing plate 10 is arranged above the transceiver modules 40, and is connected to the emitting plate and the receiving plate of each transceiver module through a flexible flat cable 401. The processing plate 10 is provided with a through hole at a corresponding position at which the flexible flat cable is arranged, so that the flexible flat cable enters and is connected to a socket on the processing plate 10.

In an embodiment, shielding covers are respectively provided on the emitting plate 11 and/or the receiving plate 12 to provide electromagnetic shielding for the emitting plate or the receiving plate. For example, the emitting plate 11 is provided with a first shielding cover, and the receiving plate 12 is provided with a second shielding cover. A material of the shielding cover is metal, and the shielding cover covers a component of the emitting plate 11 and/or the receiving plate 12, and is configured to shield an electromagnetic signal of the emitting plate 11 and/or the receiving plate 12, thereby preventing the electromagnetic signals generated by the emitting plate 11 and/or the receiving plate 12 from causing interference to another component.

The galvanometer 13 is configured to adjust an outgoing direction of a laser signal, and to receive an echo signal and deflect the echo signal to the transceiver module, where the echo signal passes through a beam splitter and a receiving terminal focusing lens group in the transceiver module and is then directed toward the receiving plate. Specifically, the galvanometer 13 is configured to directionally deflect the laser signal transmitted by the emitting plate 11, and the processing plate 10 transmits a galvanometer drive signal to the galvanometer 13, to control a deflection angle of the galvanometer 13, thereby changing the outgoing direction of the laser signal. For example, the processing plate 10 controls the galvanometer 13 to perform sinusoidal scanning in a horizontal direction and a vertical direction.

The galvanometer 13 can be a one-dimensional galvanometer or a two-dimensional galvanometer. For example, the galvanometer 13 can be a MEMS (Micro-Electro-Mechanical System) galvanometer, or other mechanical or electronic galvanometer. This application also includes any possible form of galvanometer.

The processing plate 10 is configured to sample the echo signal and control the deflection angle of the galvanometer. Specifically, the processing plate 10 performs conditioning on an electrical signal generated by the receiving plate 12. A conditioning process includes, but is not limited to, one or more of debouncing, filtering, protection, level conversion, and isolation. After conditioning, the electrical signal is further sampled to obtain a sampled signal, and a scanning image is generated based on the sampled signal. The scanning image includes multiple point clouds, a position of the point cloud is related to a deflection angle of the galvanometer 13 in a horizontal direction and a vertical direction, and a detection distance is related to intensity of the echo signal.

The processing plate 10 is also configured to control the deflection angle of the galvanometer 13, and the deflection angle of the galvanometer 13 is used to control the deflection direction of the emergent laser. The processing plate 10 transmits the galvanometer drive signal to the galvanometer 13. The galvanometer drive signal can be a sinusoidal signal, and frequency and amplitude of a sine wave can be determined according to actual needs. In addition, the processing plate 10 also collects a feedback signal (for example, a horizontal deflection angle and a vertical deflection angle) from the galvanometer 13, to implement closed-loop control of the galvanometer 13 based on the feedback signal. For example, frequency of the sinusoidal signal is equal to or approximately equal to resonance frequency of the galvanometer 13. The galvanometer drive signal controls the galvanometer 13 to perform scanning in a corresponding scanning mode, and the scanning mode can be any one of a sine wave mode, a cosine wave mode, or a triangular wave mode.

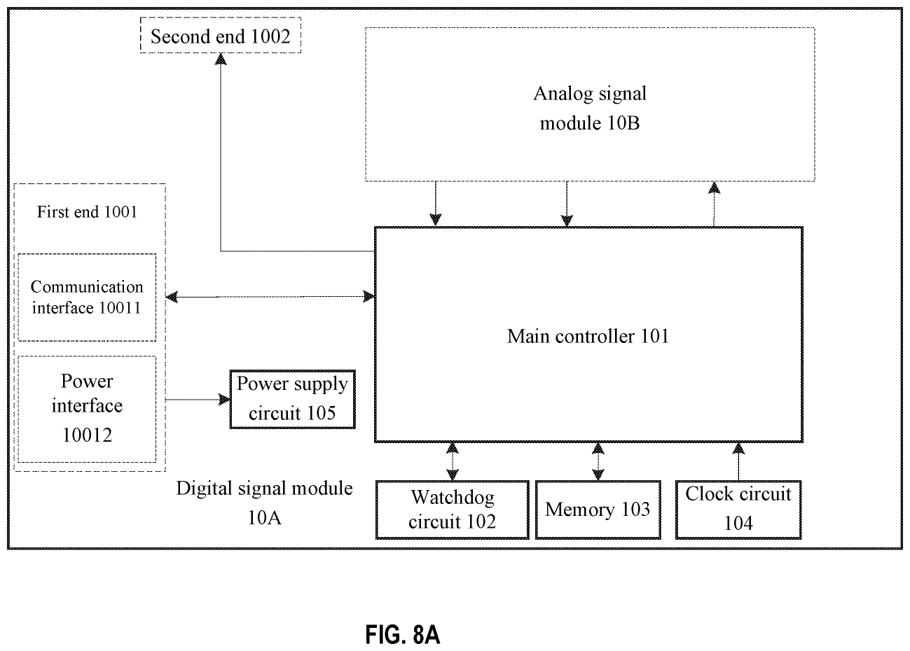

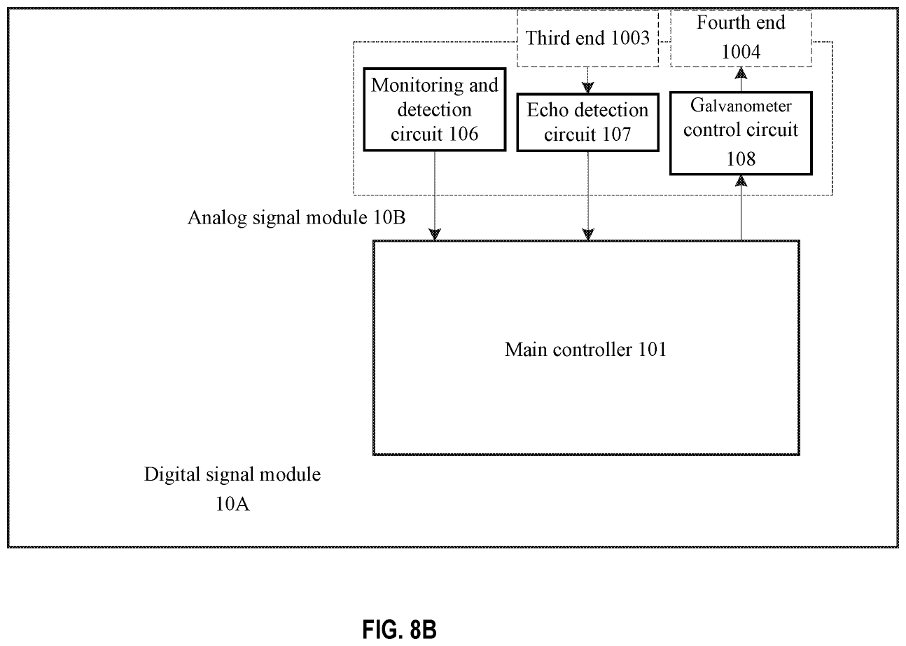

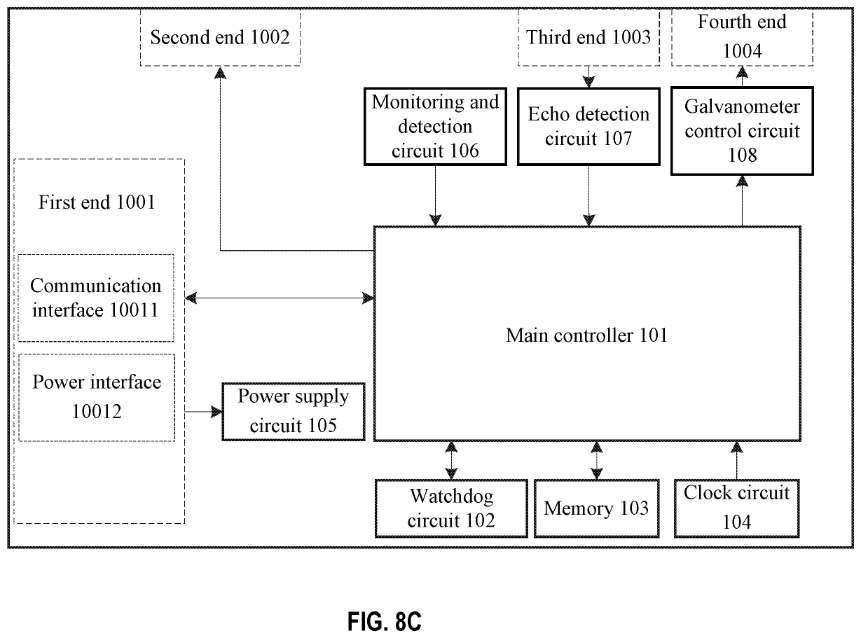

In an embodiment, referring to FIG. 8A, FIG. 8A is a schematic structural diagram of a processing plate according to an embodiment. The processing plate 10 includes a digital signal module 10A and an analog signal module 10B. The digital signal module 10A includes a main controller 101, a memory 103, a watchdog circuit 102, a clock circuit 104, and a power supply circuit 105. An interface of the processing plate 10 further includes a first end 1001 (including a communication interface 10011 and a power interface 10012) and a second end 1002.

The main controller 101 is separately connected to the memory 103, the watchdog circuit 102, the clock circuit 104, and the analog signal module 10B. The main controller 101 is connected to the emitting plate 11 through the second end 1002 of the processing plate 10. The main controller 101 is connected to a first end of an interface plate 14 through the first end 1001 of the processing plate 10. A first end of the power supply circuit 105 is connected to the first end of the interface plate 14.

The memory 103 is configured to store a computer program.

The watchdog circuit 102, also referred to as a watchdog timer (watchdog timer), is a timer circuit configured to reset the main controller when the main controller 101 fails. Specifically, the main controller 101 periodically sends a pulse signal to the watchdog circuit 102, namely, kicking the dog (kicking the dog/service the dog). When the main controller 101 fails (for example, executes an infinite loop), the main controller 101 cannot send the pulse signal to the watchdog circuit 102. When the watchdog circuit 102 does not receive the pulse signal within a preset duration, the watchdog circuit 102 sends a reset signal to the main controller 101 to instruct the main controller 101 to perform a reset operation.

The clock circuit 104 is used for timing. Specifically, the clock circuit 104 is configured to generate a clock signal, and the clock circuit 104 provides the main controller 101 with a working clock and a sampling clock. The main controller 101 samples an electrical signal from the analog signal module 10B at a preset sampling frequency to obtain a sampled signal, and invokes the computer program stored in the memory 103 to process the sampled signal to obtain a scanning image.

The main controller 101 is further configured to sample the echo signal by using the analog signal module 10B and the clock circuit 104. Specifically, the main controller 101 may be a CPU, an NP, or a combination of the CPU and the NP. The main controller 101 may further include a hardware chip. The forgoing hardware chip can be an ASIC, a PLD, or a combination thereof. The forgoing PLD may be a CPLD, an FPGA, a GAL or any combination thereof. The main controller 101 is also connected to the interface plate 14 by using the communication interface 10011. That is, the main controller communicates with a peripheral device via the communication interface 10011. The main controller 101 is further configured to control the emitting plate 11 through the second end 1002 to transmit a laser signal, and to instruct the analog signal module 10B to receive the echo signal through the receiving plate 12.

The power supply circuit 105 is configured to receive a regulated voltage signal from the interface plate 14 by using the power interface 10012, convert the regulated voltage signal into multiple working voltage signals of different voltage values, and provide the multiple working voltage signals to each circuit in the processing plate.

Referring to FIG. 8B, FIG. 8B is a schematic structural diagram of a processing plate according to an embodiment of this application. The analog signal module 10B includes a monitoring and detection circuit 106, an echo detection circuit 107, and a galvanometer control circuit 108.

The main controller 101 is respectively connected to the first end of the echo detection circuit 107, the monitoring and detection circuit 106, and the first end of the galvanometer control circuit 108. The second end of the echo detection circuit 107 is connected to the receiving plate 12 via the third end 1003 of the processing plate 10, and the second end of the galvanometer control circuit 108 is connected to the galvanometer 13 via the fourth end 1004 of the processing plate 10.

The monitoring and detection circuit 106 is configured to monitor whether the main controller 101 fails. For example, the monitoring and detection circuit 106 detects whether the main controller 101 is in an abnormal state such as overheating, an excessively high operating voltage, or an excessively low operating voltage, to raise an alarm and/or perform a safety protection operation.

The echo detection circuit 107 is configured to perform conditioning on the echo signal of the receiving plate 12 and send the echo signal to the main controller 101 after conditioning. The conditioning process includes one or more of debouncing, filtering, protection, level conversion, and isolation.

The main controller 101 is also configured to control the deflection angle of the galvanometer 13 by using the galvanometer control circuit 108. Specifically, the main controller 101 sends a galvanometer drive signal to the galvanometer control circuit 108, and the galvanometer control circuit 108 is configured to adjust the deflection angle of the galvanometer 13 based on the galvanometer drive signal by using the fourth end 1004 of the processing plate 10. The galvanometer drive signal may be a superposition of a triangular wave signal and a sine wave signal to control the galvanometer 13 to perform scanning in the horizontal direction and the vertical direction.

In this embodiment, referring to FIG. 8C, FIG. 8C is a schematic structural diagram of a processing plate according to an embodiment of this application. The processing plate includes a digital signal module 10A, an analog signal module 10B, the first end 1001 (including a communication interface 10011 and a power interface 10012), the second end 1002, the third end 1003 and the fourth end 1004. The digital signal module 10A includes a main controller 101, a memory 103, a watchdog circuit 102, a clock circuit 104, and a power supply circuit 105. The analog signal module 10B includes a monitoring and detection circuit 106, an echo detection circuit 107, and a galvanometer control circuit 108. For a connection method and a working principle of the foregoing components, refer to description of FIG. 8A and FIG. 8B. Details are not described herein again.

In this embodiment, a linear distance between the analog signal module 10B and the main controller 101 included in the digital signal module 10A is greater than a distance threshold. For example, a linear distance between the monitoring and detection circuit 106 and the main controller 101 is greater than a first distance threshold; a linear distance between the echo detection circuit 107 and the main controller 101 is greater than a second distance threshold; and a linear distance between the galvanometer control circuit 108 and the main controller 101 is greater than the third distance threshold. The linear distance between the analog signal module and the digital signal module is arranged, to implement digital-analog separation, which effectively improves anti-interference capability of the analog signal module and the digital signal module, thereby improving working reliability of the processing plate.

The interface plate 14 is configured to communicate with a peripheral device by using an external end of the interface plate, and receive a voltage signal provided by the peripheral device. The communication interface includes, but is not limited to, an RS232 interface, a USB interface, or a CAN interface. The peripheral device includes any electronic device or set of electronic devices with a communication function and a charging function.

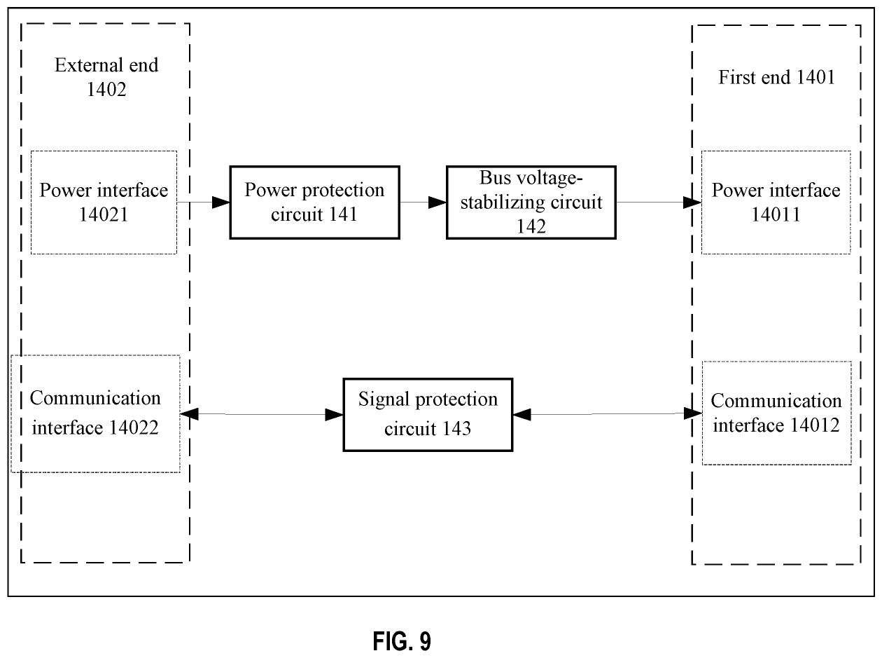

In an embodiment, referring to FIG. 9, FIG. 9 is a schematic structural diagram of an interface plate according to an embodiment of this application. The interface plate 14 includes a bus voltage-stabilizing circuit 142, a power protection circuit 141, and a signal protection circuit 143.

The first end of the power protection circuit 141 is connected to the power interface 14021 at the external end 1402 of the interface plate 14. The first end of the signal protection circuit 143 is connected to the communication interface 14022 at the external end 1402 of the interface plate 14, and the second end of the power protection circuit 141 is connected to the first end of the bus voltage-stabilizing circuit 142. The second end of the bus voltage-stabilizing circuit 142 and the second end of the signal protection circuit 143 are connected to the first end of the interface plate 14.

The power protection circuit 141 is configured to perform overvoltage protection and overcurrent protection on the interface plate 14 to prevent damage to the components of the LiDAR caused by an excessively large instantaneous voltage or instantaneous current. In addition, the power protection circuit 141 is also configured to filter out interference caused by the external power source to the LiDAR, and to filter out the interference caused by the LiDAR to the external power source.

The bus voltage-stabilizing circuit 142 is configured to stabilize a voltage signal provided by the peripheral device to obtain a stable voltage signal, and send the stable voltage signal to the processing plate 10 via the first end 1401 of the interface plate 14. For example, the voltage signal provided by the peripheral device is a 5V direct current (DC) voltage signal, and is sent to the bus voltage-stabilizing circuit 142 via the power interface 14021 and the power protection circuit 141. The bus voltage-stabilizing circuit 142 stabilizes an external voltage signal with voltage fluctuation to obtain a target voltage signal of a constant voltage value, to ensure the stability of a post-stage power source, and sends the stable voltage signal to the processing plate 10 via the power interface 14011.

The signal protection circuit 143 is configured to suppress interference when the interface plate 14 communicates with the peripheral device. Specifically, the interface plate 14 and the processing plate 10 communicate with the peripheral device by using the communication interface 14022 and the communication interface 14012, that is, the interface plate and the processing plate receive an instruction or data sent by the peripheral device, or send an instruction or data to the peripheral device. During communication, the signal protection circuit 143 is configured to offer protection to the communication interface 14022 and the communication interface 14012, for example, overvoltage protection, overcurrent protection, and interference suppression, thereby improving reliability of communication.

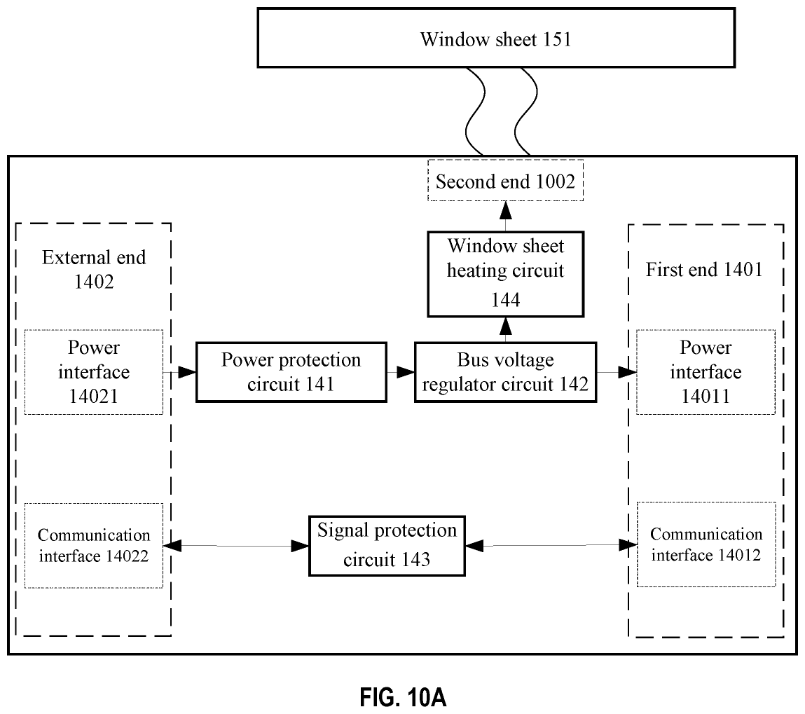

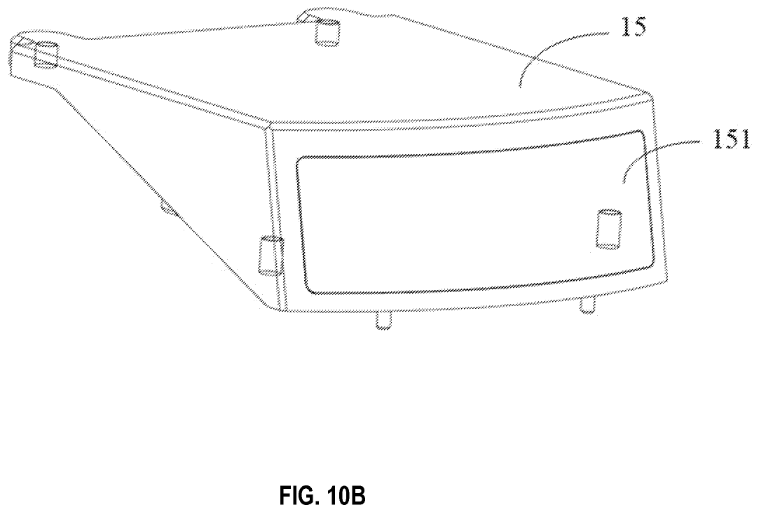

In an embodiment, referring to FIG. 10A, FIG. 10A is a schematic structural diagram of an interface plate according to an embodiment of this application. The interface plate 14 includes a bus voltage-stabilizing circuit 142, a power protection circuit 141, a signal protection circuit 143, and a window sheet heating circuit 144. The LiDAR also includes a window sheet 151.

The first end of the window sheet heating circuit 144 is connected to the third end of the bus voltage-stabilizing circuit 142, and the second end of the window sheet heating circuit 144 is connected to the window sheet 151 by using the second end 1002 of the interface plate 14. Referring to FIG. 10B, FIG. 10B is a schematic structural diagram of a housing according to an embodiment of this application. A housing 15 and a window sheet 151 are included, and the window sheet 151 is arranged on the housing 15. The window is made of a material with strong transparency performance, and is configured to allow the laser signal to be transmitted out of the LiDAR and allow the echo signal to be received by the receiving plate.

In this embodiment, the bus voltage-stabilizing circuit 142 is also configured to send the stable voltage signal to the window sheet heating circuit 144, and the window sheet heating circuit 144 is configured to heat the window sheet 151 by using the stable voltage signal. Specifically, the window sheet heating circuit 144 converts electrical energy from the peripheral device into thermal energy to defrost the window sheet 151, thereby preventing water vapor on the window sheet 151 from affecting intensity and direction of the laser signal and the echo signal.

For example, the window sheet heating circuit 144 includes a heating plate composed of a high-resistance material and a heating circuit. The heating plate is closely attached to the window sheet 151, the heating circuit is electrically connected to the heating plate, and the heating circuit transfers electrical energy to the heating plate by using a stable voltage signal, to load the stable voltage signal onto the heating plate. The heating plate converts the electrical energy into thermal energy, and transfers the thermal energy to the window sheet, to defrost the window sheet.

In this embodiment, the window sheet is defrosted by the heating circuit, to prevent the water vapor on the window sheet from affecting the intensity and direction of the laser signal and the echo signal, thereby improving working performance of the LiDAR.

The LiDAR provided in this application includes the housing, the processing plate, the emitting plate, the receiving plate, the galvanometer, and the interface plate. The processing plate, the emitting plate, the receiving plate, the galvanometer, and the interface plate are arranged inside the housing. In this application, the processing plate samples the echo signal and controls the deflection angle of the galvanometer, and different boards are provided to realize functions of communicating with the peripheral device, transmitting the laser signal, receiving the echo signal, and so on. The boards are properly arranged and integrated, to avoid a problem that a component is damaged due to poor heat dissipation caused by implementing all LiDAR functions in the related art by one board, and to avoid a problem of oversize volume of the LiDAR due to an excessively large number of boards in each hardware, which satisfies a miniaturization and integration requirement for the LiDAR on the premise of ensuring a heat dissipation capability and anti-interference of the LiDAR.

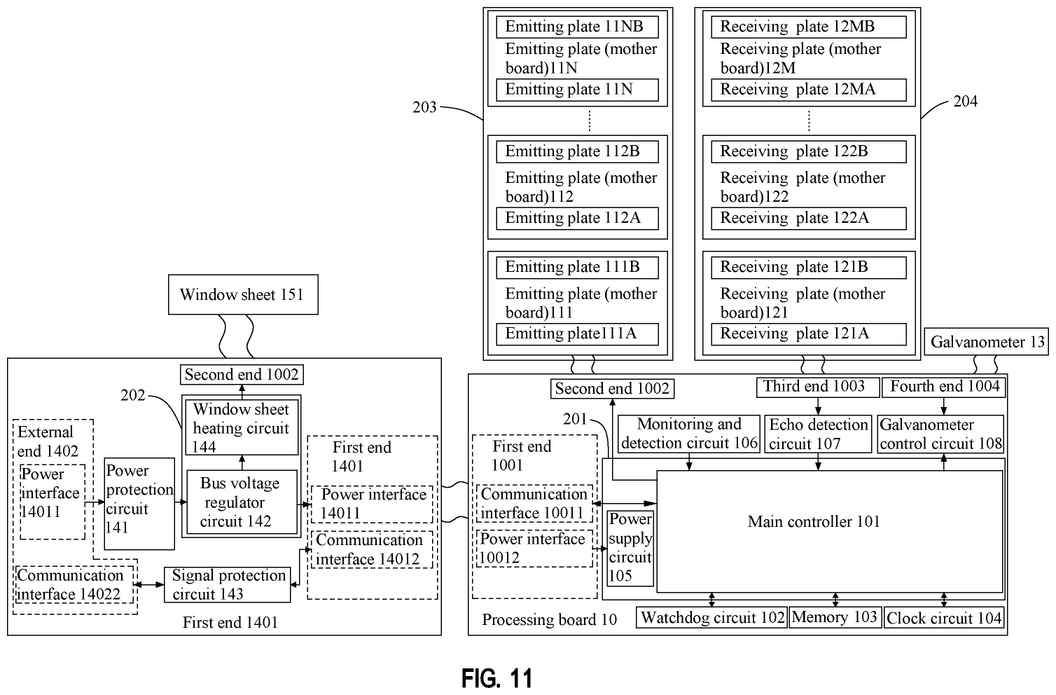

Referring to FIG. 11, FIG. 11 is a schematic structural diagram of a LiDAR according to an embodiment of this application. The LiDAR includes a housing (not shown in FIG. 11), a processing plate 10, a transceiver module 401 (including N emitting plates 11 and M receiving plates 12), a galvanometer 13, and an interface plate 14. The first end 1401 of the interface plate 14 is connected to the first end 1001 of the processing plate 10, and the second end 1002, the third end 1003, and the fourth end 1004 of the processing plate 10 are respectively connected to the emitting plate 11, the receiving plate 12, and the galvanometer 13. The foregoing connection is an electrical connection. For example, the emitting plate 11 and the processing plate 10 are electrically connected through a flexible flat cable or socket, and the galvanometer 13 and the processing plate 10 are electrically connected through a flexible flat cable or socket. This application includes any electrical connection method.

For structures of the processing plate 10, the emitting plate 11, the receiving plate 12, the galvanometer 13, and the interface plate 14, refer to FIG. 6 to FIG. 10B. Details are not described herein again.

In this embodiment, heat sources of the processing plate 10 are concentrated in the main controller 101 and the power supply circuit 105. The processing plate 10 further includes a first heat dissipation component 601, and the main controller 101 and the power supply circuit 105 are attached to an inner wall of the housing through the first heat dissipation component.

Heat sources of the interface plate 14 are concentrated in the bus voltage-stabilizing circuit 142 and the window sheet heating circuit 144. The interface plate 14 also includes a second heat dissipation component 602, and the bus voltage-stabilizing circuit 142 and the window sheet heating circuit 144 are attached to the inner wall of the housing through the second heat dissipation component 602.

The LiDAR also includes a third heat dissipation component 603 and a fourth heat dissipation component 604. In the transceiver module 401, a printed circuit plate of the emitting plate 11 and a printed circuit plate of the receiving plate 12 are respectively attached to the inner wall of the housing through the third heat dissipation component 603 and the fourth heat dissipation component 604.

The above heat dissipation component is made of a high-thermal conductivity material. In this application, the heat dissipation component is used to attach the components operating as heat sources in the LiDAR to the inner wall of the housing, so that heat generated by each component during working is conducted to the housing, thereby improving heat dissipation efficiency of the LiDAR.

The LiDAR provided in this application includes the housing, the processing plate, the emitting plate, the receiving plate, the galvanometer, and the interface plate. The processing plate, the emitting plate, the receiving plate, the galvanometer, and the interface plate are arranged inside the housing. In this application, the processing plate samples the echo signal and controls the deflection angle of the galvanometer, and different boards are provided to realize functions of communicating with the peripheral device, transmitting the laser signal, receiving the echo signal, and so on. The boards are properly arranged and integrated, to avoid a problem that a component is damaged due to poor heat dissipation caused by implementing all LiDAR functions in the related art by one board, and to avoid a problem of oversize volume of the LiDAR due to an excessively large number of boards in each hardware, which satisfies a miniaturization and integration requirement for the LiDAR on the premise of ensuring a heat dissipation capability and anti-interference of the LiDAR.

The person skilled in the art may clearly understand that the technology in the embodiments of the present application may be implemented by software plus necessary general-purpose hardware. The general-purpose hardware includes a general-purpose integrated circuit, a general-purpose CPU, a general-purpose memory, a general-purpose device, etc. Of course, the technology in the embodiments of the present invention may be implemented by dedicated hardware including a dedicated integrated circuit, a dedicated CPU, a dedicated memory, a dedicated component, etc., but in many cases, the general-purpose hardware is a better implementation. Based on this understanding, the technical solutions in the embodiments of the present invention may be essentially embodied in the form of a software product or the part that contributes to the related art may be embodied in the form of the software product. The software product may be stored in a storage medium, such as a read-only memory (ROM), a random access memory (RAM), a magnetic disk, an optical disks, etc., including a plurality of instructions to make a computer apparatus (which may be a personal computer, a server, or a network device) to perform a method described in each embodiment or some parts of the embodiment of the present invention.

The various embodiments in this specification are described in a progressive manner. The same or similar parts between the various embodiments may be referred to each other. Each embodiment focuses on the difference from other embodiments. In particular, as for a system embodiment, since the system embodiment is basically similar to a method embodiment, the description is relatively simple. For related parts, please refer to the part of the description of the method embodiment.

The embodiments of the present invention described above do not constitute a limitation to the protection scope of the present invention. Any modification, equivalent replacement and improvement made within the spirit and principle of the present invention shall be included within the protection scope of the present invention.

What is claimed is:

1. A LiDAR, comprising:
a housing, an analog plate, a digital plate, an emitting plate, a receiving plate, a galvanometer, and an interface plate,
wherein the analog plate, the digital plate, the emitting plate, and the receiving plate are arranged inside the housing;
wherein the emitting plate is configured to emit an emergent laser;
wherein the receiving plate is configured to receive a reflected laser formed by the emergent laser passing through a target object, and to convert the reflected laser into first electrical signals;
wherein the galvanometer is configured to directionally deflect the emergent laser;
wherein the analog plate is configured to control the deflection angle of the galvanometer, and to condition the first electrical signals to obtain second electrical signals;
wherein the digital plate is configured to sample the second electrical signals to obtain sampled signals, and to generate a scanned image according to the sampled signals; and
wherein the receiving plate comprises a communication interface and a power interface, and wherein the communication interface is configured to communicate with an external apparatus and the power interface is configured to input an external voltage signal.

2. The LiDAR according to claim 1, wherein the interface plate further comprises:
a heating circuit, a bus voltage-stabilizing circuit, a power protection circuit, and an interface protection circuit,
wherein the power protection circuit is configured to perform overvoltage protection and overcurrent protection for the interface plate;
wherein the bus voltage-stabilizing circuit is configured to stabilize the external voltage signals to obtain bus voltage signals;
wherein the heating circuit is configured to use the bus voltage signals to transmit electrical energy to a window heating sheet; and
wherein the interface protection circuit is configured to suppress interference of the communication interface.

3. The LiDAR according to claim 2, wherein the interface plate further comprises a first heat dissipation component, and wherein the bus voltage-stabilizing circuit is attached to an inner wall of the housing via the first heat dissipation component.

4. The LiDAR according to claim 5, wherein the digital plate comprises:
a main controller, a storage device, a watchdog circuit, a clock circuit, a sampling circuit, and a first power supply circuit,
wherein the storage device is configured to store a computer program;
wherein the watchdog circuit is configured to reset the main controller when the main controller fails;
wherein the clock circuit is configured to generate clock signals;
wherein the sampling circuit is configured to sample the second electrical signals according to the clock signals to obtain sampled signals;
wherein the main controller is configured to call the computer program to process the sampled signals to obtain a scanned image; and
wherein the first power supply circuit is configured to convert the bus voltage signals into a plurality of working voltage signals with different voltage values, and to provide the plurality of working voltage signals to each circuit in the digital plate.

5. The LiDAR according to claim 1, wherein the digital plate is divided into an analog signal region and a digital signal region,
wherein the clock circuit, the sampling circuit, and the first power supply circuit are positioned in the analog signal region, and wherein the main controller, the memory, and the watchdog circuit are positioned in the digital signal region.

6. The LiDAR according to claim 4, wherein the digital plate further comprises a second heat dissipation component, and
wherein the main controller, the sampling circuit and the first power supply circuit are attached to an inner wall of the housing via the second heat dissipation component.

7. The LiDAR according to claim 1, wherein the analog plate comprises an emitting power supply circuit, an echo conditioning circuit, a receiving power supply circuit, a galvanometer drive circuit, a second power supply circuit, and a control unit, and
wherein the second power supply circuit is configured to convert the bus voltage signals into first voltage signals and second voltage signals;
wherein the emitting power supply circuit is configured to use the first voltage signals to supply power to the emitting plate;
wherein the receiving power supply circuit is configured to use the second voltage signals to supply power to the receiving plate;
wherein the echo conditioning circuit is configured to receive first electrical signals from the receiving plate, and to condition the first electrical signals to obtain second electrical signals;
wherein the control unit is configured to generate galvanometer drive signals, and to send the galvanometer drive signals to the galvanometer drive circuit; and
wherein the galvanometer drive circuit is configured to adjust a deflection angle of the galvanometer according to the galvanometer drive signals.

8. The LiDAR according to claim 7, wherein the analog plate is divided into a digital signal region and an analog signal region, and
wherein the control unit is positioned in the digital signal region, and the emitting power supply circuit, the echo conditioning circuit, the receiving power supply circuit, the galvanometer drive circuit, and the second power supply circuit are positioned in the analog signal region.

9. The LiDAR according to claim 1, further comprising a third heat dissipation component,
wherein a printed circuit plate of the emitting plate is attached to an inner wall of the housing via the third heat dissipation component;
wherein the emitting plate is connected to the analog plate via a flexible flat cable; and
wherein material of the printed circuit plate in the emitting plate is ceramics.

10. The LiDAR according to claim 1, wherein a first shielding cover is provided on the emitting plate to electromagnetically shield the emitting plate.

11. The LiDAR according to claim 1, wherein a second shielding cover is provided on the receiving plate to electromagnetically shield the receiving plate, and wherein the receiving plate further comprises a signal amplifier configured to amplify the first electrical signals.

12. A LiDAR, comprising:
a housing, a processing plate, an emitting plate, a receiving plate, a galvanometer, and an interface plate;
wherein the processing plate, the emitting plate, the receiving plate, the galvanometer, and the interface plate are arranged inside the housing; a first end of the interface plate is connected to a first end of the processing plate; and a second end, a third end, and a fourth end of the processing plate are respectively connected to the emitting plate, the receiving plate, and the galvanometer;
wherein the emitting plate is configured to emit an emergent laser;
wherein the receiving plate is configured to receive a reflected laser formed by the emergent laser passing through a target object, and to convert the reflected laser into reflected signals;
wherein the galvanometer is configured to directionally deflect the emergent laser and the reflected laser;
wherein the processing plate is configured to control the emitting plate, the receiving plate, and the galvanometer, and to process the reflected signals;
wherein the interface plate is configured to communicate with a peripheral device by using an external end of the interface plate, and to receive a voltage signal provided by the peripheral device.

13. The LiDAR according to claim 12, wherein the processing plate comprises a digital signal module and an analog signal module;
wherein the digital signal module comprises a main controller; and
wherein a linear distance between the analog signal module and the main controller is greater than a distance threshold.

14. The LiDAR according to claim 13, wherein the digital signal module of the processing plate further comprises:
a storage device, a watchdog circuit, a clock circuit, and a power supply circuit;
wherein the main controller is connected to the storage device, the watchdog circuit, the clock circuit, the analog signal module, the emitting plate, and the first end of the interface plate;
wherein the storage device is configured to store a computer program;
wherein the watchdog circuit is configured to reset the main controller when the main controller fails;
wherein the clock circuit is configured to generate clock signals;
wherein the main controller is configured to call the computer program to sample the reflected signals via the analog signal module and the clock circuit; and
wherein the power supply circuit is configured to receive a regulated voltage signal from the interface plate by using the power interface, convert a regulated voltage signal into multiple working voltage signals of different voltages values, and provide the multiple working voltage signals to each circuit in the processing plate.

15. The LiDAR according to claim 14, wherein the analog module further comprises a monitoring and detection circuit, an echo detection circuit, and a galvanometer control circuit;
wherein the main controller is respectively connected to a first end of the echo detection circuit, the monitoring and detection circuit, and a first end of the galvanometer control circuit; a second end of the echo detection circuit is connected to the receiving plate; a second end of the galvanometer control circuit is connected to the galvanometer;
wherein the monitoring and detection circuit is configured to monitor whether the main controller fails;
wherein the echo detection circuit is configured to perform conditioning on the reflected signals of the receiving plate and to send the reflected signals to the main controller after conditioning; and
wherein the main controller is also configured to control a deflection angle of the galvanometer via the galvanometer control circuit.

16. The LiDAR according to claim 12, wherein a number of the emitting plate is at least one, and each emitting plate is in a form of two layered boards of a mother board and a sub-board.

17. The LiDAR according to claim 12, wherein a number of the receiving plate is at least one, and each receiving plate is in a form of two layered boards of a mother board and a sub-board.

18. The LiDAR according to claim 16, wherein the mother board of the emitting plate is a rigid-flex board, and the sub-board is a ceramic board with heat coefficient exceeding a threshold.
